(19) United States
(12) Patent Application Publication
(10) Pub. No.: US 2011/0223769 A1
(43) Pub. Date: Sep. 15, 2011

(54) METHOD OF FABRICATING A SEMICONDUCTOR DEVICE

(76) Inventors: Nikka Ko, Mie-ken (JP); Katsunori Yahashi, Mie-ken (JP); Kei Hattori, Kanagawa-ken (JP)

(21) Appl. No.: 13/026,527

(22) Filed: Feb. 14, 2011

(30) Foreign Application Priority Data
Mar. 15, 2010 (JP) P2010-057219

(51) Int. Cl. H01L 21/31

(52) U.S. Cl. 438/703; 257/E21.24

(57) ABSTRACT

According to one embodiment, a method of fabricating a semiconductor device, including, selectively forming a first film as a core member on a film to be processed, forming a second film on a side surface and an upper surface of the core member, and on an upper surface of the film to be processed to cover the film, the second film which is constituted with same material as the first film and is doped with impurities being different in amount from impurities in the first film, removing the second film on the core member and on the film to be processed to form a sidewall mask constituted with the second film on the side surface of the core member, selectively removing the core member, and etching the film to be processed using the sidewall mask film as a mask.

### CROSS REFERENCE TO RELATED APPLICATION

This application is based upon and claims the benefit of priority from prior Japanese Patent Application No. 2010-057219, filed on Mar. 15, 2010, the entire contents of which are incorporated herein by reference.

### FIELD

Exemplary embodiments described herein generally relate to a method of fabricating a semiconductor.

### BACKGROUND

Recently, a method for forming a pattern having a dimension less than resolution limitation in lithography (limitation of line width in exposure technique) have been required with accompanying miniaturization of a semiconductor element. As one approach, it is known that a sidewall pattern as a sidewall mask is formed on a sidewall of a dummy pattern as a core member and a film to be processed is etched using the sidewall mask as a mask.

After forming the sidewall mask in such a manner, the core member between the sidewall masks is removed by wet-cleaning, so that a fine mask, which is constituted with the sidewall mask, is formed.

However, the sidewall mask is tilted due to stress or the like generated in the sidewall mask or the core member, so that accuracy of the mask pattern may be deteriorated.

Hence, a method of fabricating a semiconductor device has been disclosed. A covering film composed of an amorphous material is formed to cover on an upper and a side surface of a core member. The covering film other than a portion which is formed on the side surface of the core member is removed to leave the portion of the covering film. Accordingly, a sidewall mask is formed on the sidewall of the core member. After crystallizing the side wall mask, the core member is removed.

The sidewall mask with internal compressive stress is formed by crystallizing the sidewall mask. As a result, a deformation of the sidewall mask by tilting is controlled, and the pattern having fine lines and spaces can be precisely formed.

However, the disclosed method of fabricating the semiconductor device includes a modification process for crystallizing the amorphous material in high temperature. Therefore, the method has a problem that the fabricating process becomes longer.

### BRIEF DESCRIPTION OF THE DRAWINGS

FIGS. 1A-1B are a plane schematic diagram in a memory cell area and a cross-sectional schematic diagram in the memory cell area along A-A line shown in FIG. 1A, respectively, showing a structure of a semiconductor device according to a first embodiment;

FIG. 2 is a cross-sectional schematic diagram showing a method of fabricating a semiconductor device according to the first embodiment;

FIGS. 3A-3D are cross-sectional schematic diagrams showing the method of fabricating the semiconductor memory device according to the first embodiment;

FIGS. 4A-4D are cross-sectional schematic diagrams showing the method of fabricating the semiconductor device according to the first embodiment;

FIG. 5 is a cross-sectional schematic diagram showing a method of fabricating a semiconductor device according to a modification of the first embodiment;

FIG. 6 is a cross-sectional schematic diagram showing a method of fabricating a semiconductor device according to a second embodiment;

FIGS. 7A-7D are cross-sectional schematic diagrams showing the method of fabricating the semiconductor device according to the second embodiment;

FIGS. 8A-8D are cross-sectional schematic diagrams showing the method of fabricating the semiconductor device according to the second embodiment.

### DETAILED DESCRIPTION

According to one embodiment, a method of fabricating a semiconductor device, including, selectively forming a first film as a core member on a film to be processed, forming a second film on a side surface and an upper surface of the core member, and on an upper surface of the film to be processed to cover the film, the second film which is constituted with same material as the first film and is doped with impurities being different in amount from impurities in the first film, removing the second film on the core member and on the film to be processed to form a sidewall mask constituted with the second film on the side surface of the core member, selectively removing the core member, and etching the film to be processed using the sidewall mask film as a mask.

Embodiments will be described below in detail with reference to the attached drawings mentioned above. Throughout the attached drawings, similar or same reference numerals show similar, equivalent or same components, and duplicative explanation on the reference numerals are omitted.

### First Embodiment

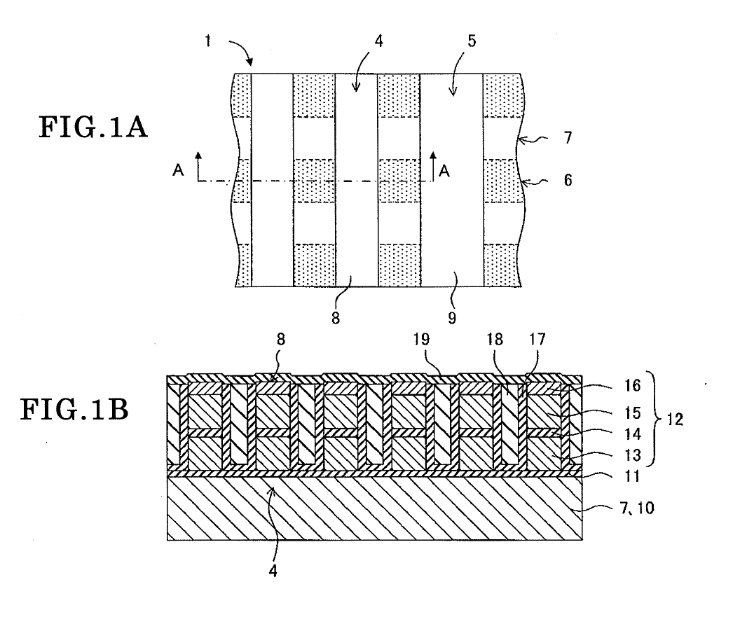

A semiconductor device and a method of fabricating the semiconductor device according to the first embodiment are described as reference from FIG. 1 to FIG. 4.

As shown in FIG. 1, a semiconductor device 1 is shown as a NAND-type flash memory device. As shown in FIG. 1A, the semiconductor device 1 includes a memory cell area in which memory cell transistors 4 are arranged as a matrix with a prescribed interval as well-known.

In the memory cell area, each of element areas 6 extending along the horizontal direction in FIG. 1A is arranged in parallel as a band along the vertical direction. The element area 6 with a prescribed width is separated by an isolation area 7 with a prescribed width. Bit lines (not shown) are arranged along the horizontal direction in an upper portion to the element area 6 which is the upper portion in the vertical direction, and word lines 8 extending along the vertical direction is arranged in parallel. Each gate electrode (gate electrode 12 mentioned below) in the memory cell transistors 4 are arranged at a crossing portion between each of the element areas 6 and each of the word lines 8.

As shown in FIGS. 1A and 1B, the memory cell transistors 4 are directly connected in the horizontal direction. A gate electrode (not shown) of a selection gate transistor 5 is arranged at an edge portion of the memory cell transistor 4 which is directly connected at the crossing portion between the element area 6 and a selection gate line 9. The memory cell transistor 4 and the selection gate transistor 5 directly connected each other as adjacent transistors share a source-drain diffusion area formed in a semiconductor substrate 10.

As shown in FIG. 1B, a gate electrode 12 in the semiconductor device 1 is formed on a surface of the element area 6 of the semiconductor substrate 10 via a silicon oxide film 11 as a tunnel insulating film or a gate insulating film. A polycrystalline silicon film 13 as a floating gate electrode film, an ONO (Oxide-Nitride-Oxide) film 14 as an inter-electrode insulating film, a silicide film 16 as a control gate electrode film are'laminated in order from a side of the silicon oxide film 11. The silicide film 16, for example, cobalt silicide, is formed by silicidation of a polycrystalline silicon film 15.

A sidewall insulating film 17 is arranged on a sidewall of the gate electrode 12 and the silicon oxide film 11 between the gate electrodes 12, and an interlayer insulating film 18 is arranged between the sidewall insulating films 17. Further, a barrier film 19 which is composed of a silicon nitride film is arranged on the gate electrode 12 and the interlayer insulating film 18. The sidewall insulating film 17, the interlayer insulating film 18 and the barrier film 19 as shown in FIG. 1B are omitted in FIG. 1A.

Next, a method of fabricating the gate electrode 12 as a pattern with line and space of the semiconductor device 1 in the total processing steps is described. The gate electrode 12 is constituted with line and space which has a finer pitch than resolution limitation in exposure technology.

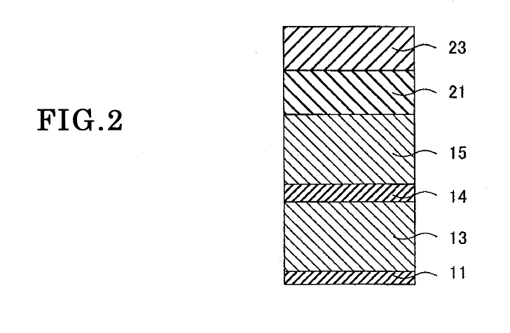

As shown in FIG. 2, a silicon oxide film 11 is formed by thermal oxidation on the semiconductor substrate 10 composed of silicon. The polycrystalline silicon film 13 doped with phosphorous (P) is formed on the silicon oxide film 11 by LPCVD (Low pressure Chemical Vapor Deposition). The ONO film 14 which is constituted with a silicon oxide film, a silicon nitride film and a silicon oxide film laminated in order is formed on the polycrystalline silicon film 13. The polycrystalline silicon film 15 doped with phosphorous is formed on the ONO film 14. A silicon nitride film 21 is formed on the polycrystalline silicon film 15, and silicon oxide film 23 is formed on the silicon nitride film 21. The silicon oxide film 23 is used as a film to be processed which has a finer pitch than resolution limitation in exposure technology.

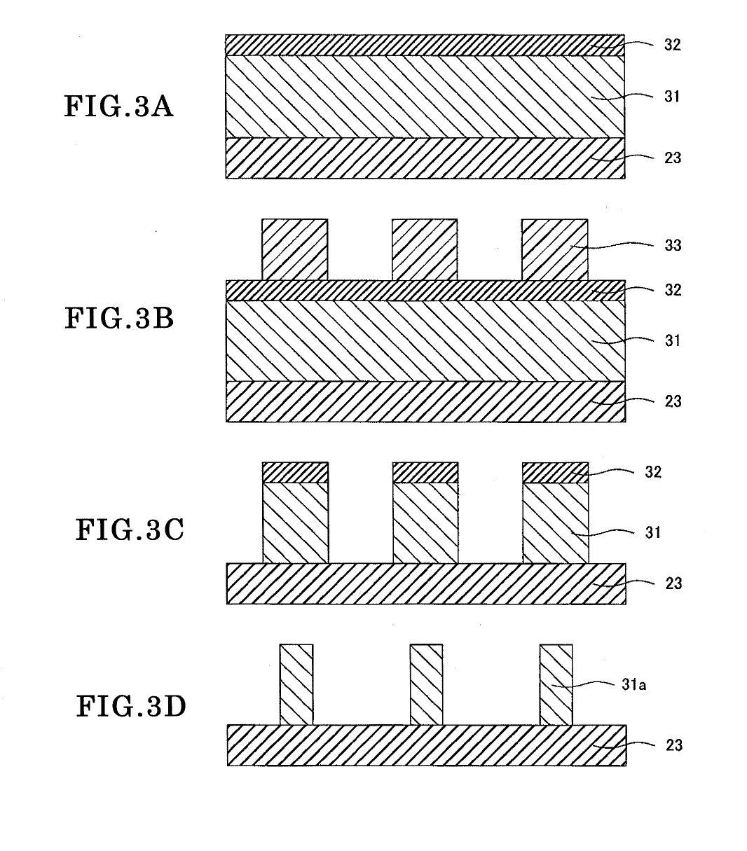

As shown in FIG. 3A, a polycrystalline silicon film 31 without doping impurities, which is called an undoped polycrystalline silicon film hereinafter, is formed as a first film on the silicon oxide film 23 by using LPCVD. The undoped polycrystalline silicon film 31 is used as a core member 31a mentioned after. A silicon nitride film 32 is formed on the polycrystalline silicon film 31.

As shown in FIG. 3B, a photo resist film 33 patterned is formed on the silicon nitride film 32. The photo resist film 33 is patterned by using lithography technology with a prescribed pitch which has width and space of resolution limitation or the vicinity in exposure technology. Further, an anti-reflection film may be formed between the silicon nitride film 32 and the photo resist film 33.

As shown in FIG. 3C, the silicon nitride film 32 is etched by RIE (Reactive Ion Etching) using the photo resist film 33 as a mask. Next, after removing the photo resist film 33, the polycrystalline silicon film 31 is etched using the patterned silicon nitride film 32 as a mask. In the etched polycrystalline silicon film 31, a width is nearly the same as an interval of closest planes which are adjacent each other.

As shown in FIG. 3D, after removing the silicon nitride film 32 by a solution, the polycrystalline silicon film 31 is slimmed. Wet etching, dry etching or a combination of wet etching and dry etching is carried out to slim the polycrystalline silicon film 31. A width and an interval of the polycrystalline silicon film 31, for example, are set to be a half and 1.5 times, respectively, as compared to those before slimming. The polycrystalline silicon film 31 after slimming is created to core members 31a which are selectively arranged as a pattern with the triple interval to the width on the silicon oxide film 23. Here, after the polycrystalline silicon film 31 is etched using the silicon nitride film 32 as a mask, the pattern is formed less than resolution limitation by slimming. However, slimming can be performed for the silicon nitride film 32 or the photo resist film 33. In this case, the pattern of the silicon nitride film 32 formed less than resolution limitation may transfer into the polycrystalline silicon film 31 without dimension conversion.

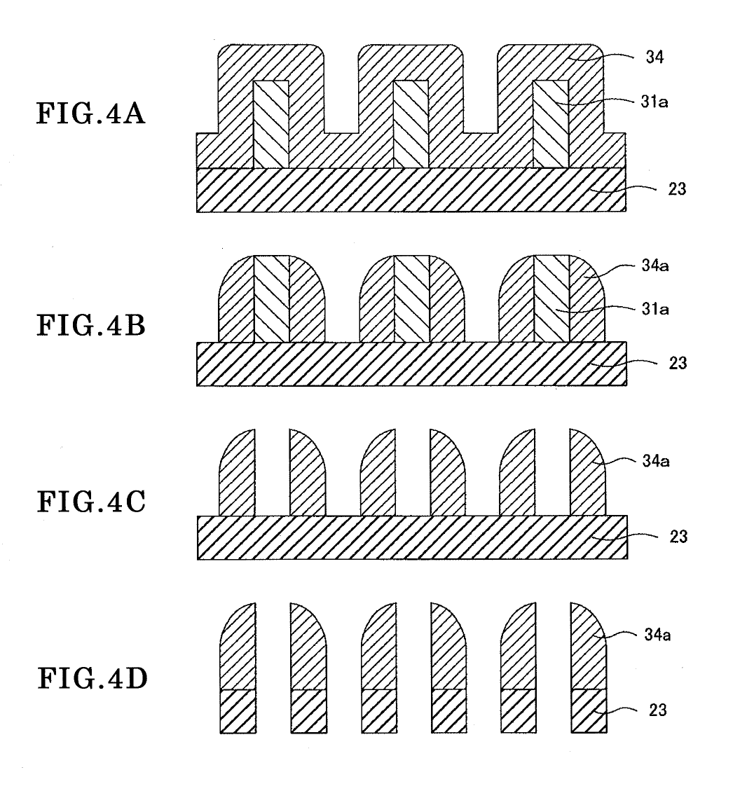

As shown in FIG. 4A, a polycrystalline silicon film 34 doped with boron (B) is formed on a surface and a sidewall of the core member 31a by LPCVD, and a surface of the silicon oxide film 23 to cover in conformal fashion. A thickness of the polycrystalline silicon film 34 is set to be slightly larger than the width of the core member 31a, as the thickness becomes smaller in etching process.

As shown in FIG. 4B, the polycrystalline silicon film 34 other than a sidewall portion formed on the sidewall of the core member 31a is removed by RIE to leave the sidewall portion of the polycrystalline silicon film 34, so that a sidewall mask film 34a is formed.

As shown in FIG. 4C, the core member 31a is selectively removed using a solution with coline to leave the sidewall mask film 34a on the silicon oxide film 23. The solution with coline can selectively remove the undoped polycrystalline silicon film 31 to the boron-doped polycrystalline silicon film 34. Further, the solution with coline can selectively remove a phosphorous-doped polycrystalline silicon film to the boron-doped polycrystalline silicon film 34. Consequently, the phosphorous-doped polycrystalline silicon film can be replaced with the undoped polycrystalline silicon film 31.

As shown in FIG. 4D, the silicon oxide film 23 which is the film to be processed is etched by wet etching or dry etching using the sidewall mask film 34a as a mask. As a result, the silicon oxide film 23 as a pattern is obtained. Successively, the underlying silicon nitride film 21 and the laminated film as a part of gate electrode 12 in the semiconductor device 1 can be processed using the patterned silicon oxide film 23 as a mask by well-known methods.

As mentioned above, the core member 31a is formed by the undoped polycrystalline silicon film 31 and the sidewall mask film 34a is formed by the boron-doped polycrystalline silicon film 34. In such a manner, a desirable pattern can be formed in the sidewall mask film 34a using the selective ratio in the solution with coline. The pattern of the sidewall mask film 34a is finer than the pattern of the polycrystalline silicon film 31 formed by lithography technology.

The same material, polycrystalline silicon, other than a difference of the impurity doping amount are used as the core member 31a and the sidewall mask film 34a. Accordingly, physical properties of the core member 31a and the sidewall mask film 34a are similar. Even when the core member 31a and the sidewall mask film 34a are formed as a state of contacting each other, stress generated at the boundary is restrained. Therefore, even when the core member 31a between the sidewall mask films 34a is removed, tilting the sidewall mask film 34a due to stress is restrained. As a result, the sidewall mask film 34a can be nearly vertically formed to the surface of the semiconductor substrate 10, so that both a width and an interval of the gate electrode 12 as an underlying layer are etched without slant. Consequently, semiconductor device 1 having stable characteristics is obtained.

Further, modification for crystallizing the amorphous material in high temperature for decreasing stress is unnecessary in fabricating the semiconductor device 1 as described in the conventional technology, so that the modification process can be omitted.

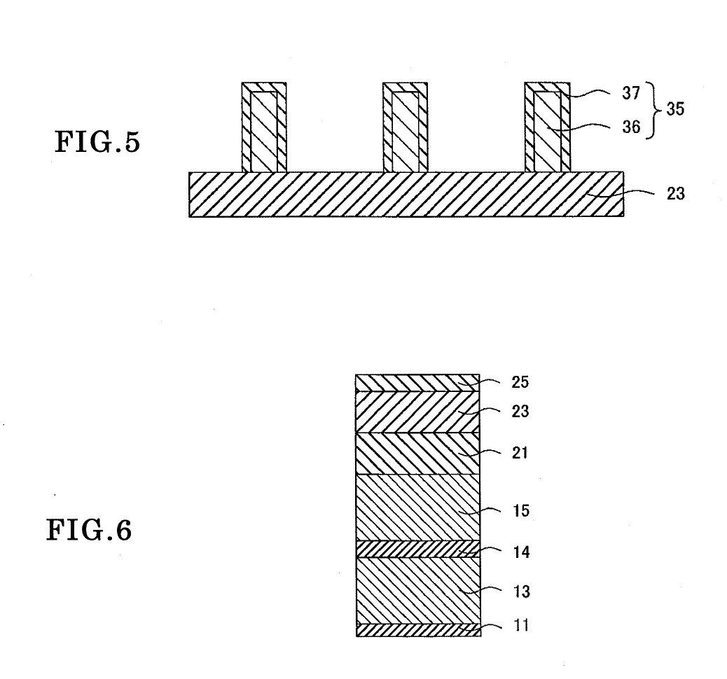

A method of fabricating a semiconductor device according to a modification of the first embodiment is described as reference to FIG. 5. The modification is different from the first embodiment that an undoped polycrystalline silicon film having a nitrided surface is used as a core member. Throughout the drawings of the modification, similar or same reference numerals with the first embodiment show similar, equivalent or same components and duplicative explanation on the reference numerals is omitted.

As shown in FIG. 5, as compared to the core member 31a in FIG. 3D of the first embodiment, a silicon nitride film 37 is formed on an undoped polycrystalline silicon film 36 in a core member 35 of the modification.

The method of fabricating a semiconductor device is described as compared to the first embodiment. Processing steps in the modification are proceeded as the same as the first embodiment to forming the core member 31a as shown in FIG. 3D. Successively, a surface of the core member 31a is plasma-nitrided to form the silicon nitride film 37 with a film thickness of nearly 0.5-3 nm. The core member 35 is constituted with the undoped polycrystalline silicon film 36 as a center portion which has the same material property as the core member 31a and a silicon nitride film 37 as the surface portion. The silicon nitride film 37 acts as a diffusion barrier film to restrain diffusing boron in boron-doped polycrystalline silicon film 34. The film thickness of the silicon nitride film 37 may be 0.5 nm or more to restrain diffusing boron. Further, an exposed surface of the silicon oxide film 23 is nitrided as the same as the polycrystalline silicon film 34 in this process to generate a silicon oxy-nitride film (not shown).

Successively, the processing steps which are the same as the first embodiment as shown in FIGS. 4A-4D can be proceeded. However, before treating by the solution with coline as shown in FIG. 4C, removing the silicon nitride film 37 on the core member 35 is inserted. Furthermore, after removing the polycrystalline silicon film 36 of the core member 35, removing the silicon nitride film 37 is also inserted. As a result, the sidewall mask film 34a which is the same as the first embodiment can be formed on the silicon oxide film 23.

In the method of fabricating a semiconductor device in the modification, diffusing boron is restrained between the core member 35 and the sidewall mask film 34a, so that the solution with coline can absolutely contribute to etching with accompanying the selection ratio. In fact, broadening at the boundary by the boron diffusion is cleared in the pattern of the sidewall mask film 34a, so that dimensional variation can be suppressed. As the film thickness of the silicon nitride film 37 is formed less than nearly 3 nm, the stress generated at the boundary is dominated to be controlled by physical property of similar polycrystalline silicon which is commonly used as the core member 35 and the sidewall mask film 34a. Processing time is not so increased as the modification in high temperature, the method of fabricating the semiconductor device in the modification of the first embodiment has the same effect as the first embodiment.

### Second Embodiment

A semiconductor device and a method of fabricating the semiconductor device according to a second embodiment are described as reference from FIG. 6 to FIG. 8. The second embodiment is different from the first embodiment that each of the core member and the sidewall mask film are silicon oxide films and has a different impurity concentration each other. Throughout the drawings of the second embodiment, similar or same reference numerals with the first embodiment show similar, equivalent or same components and duplicative explanation on the reference numerals is omitted.

As shown in FIG. 6, a silicon nitride film 25 is formed in addition on the silicon oxide film 23 which is used as the film to be processed for forming a finer pattern than resolution limitation in exposure technology.

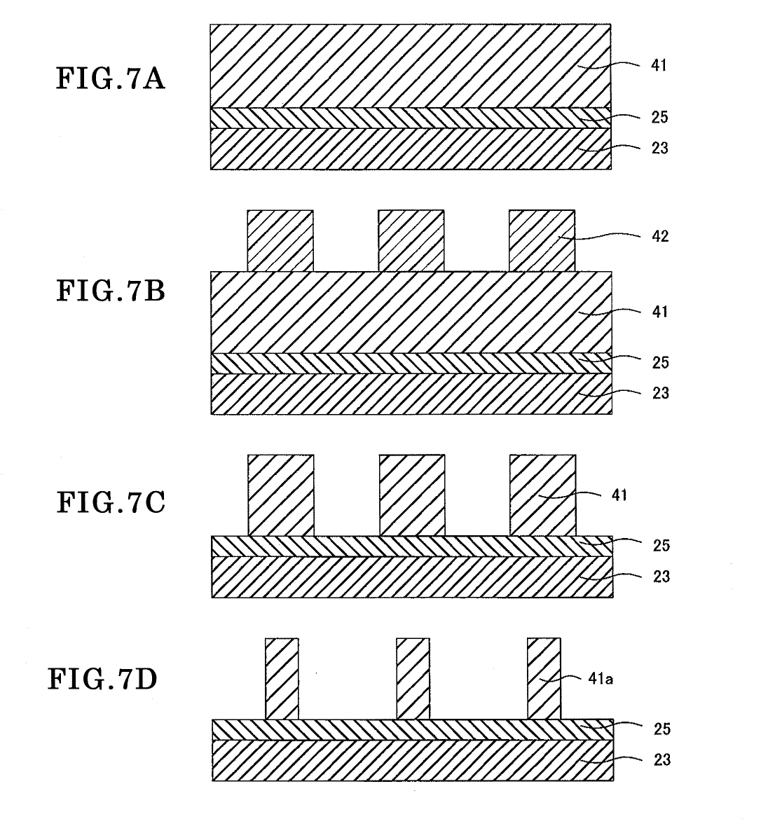

As shown in FIG. 7A, an undoped silicon oxide film 41 as a first film is formed on the silicon nitride film 25 by CVD using TEOS (Tetraethoxysilane) group as a source gas.

As shown in FIG. 7B, a photo resist film 42 with patterned is formed on the silicon oxide film 41. The photo resist film 42 is patterned by using lithography technology with a prescribed pitch which has width and space of resolution limitation or the vicinity in exposure technology. Further, an anti-reflection film may be formed between the silicon oxide film 41 and the photo resist film 42.

As shown in FIG. 7C, the silicon oxide film 41 is etched by RIE (Reactive Ion Etching) using the photo resist film 42 as a mask. Next, the photo resist film is 42 removed. In the etched silicon oxide film 41, the width is nearly the same as an interval of closest planes which are adjacent each other.

As shown in FIG. 7D, the silicon oxide film 41 is slimmed. Wet etching, dry etching or combination of wet etching and dry etching is carried out to slim the silicon oxide film 41. A width and an interval of the silicon oxide film 41, for example, are set to be a half and 1.5 times, respectively, as compared to those before slimming. The silicon oxide film 41 after slimming is created to core members 41a which are selectively arranged as a pattern with the triple interval to the width on the silicon nitride film 25. Further, slimming can be performed to the photo resist film 42 as the same as the first embodiment.

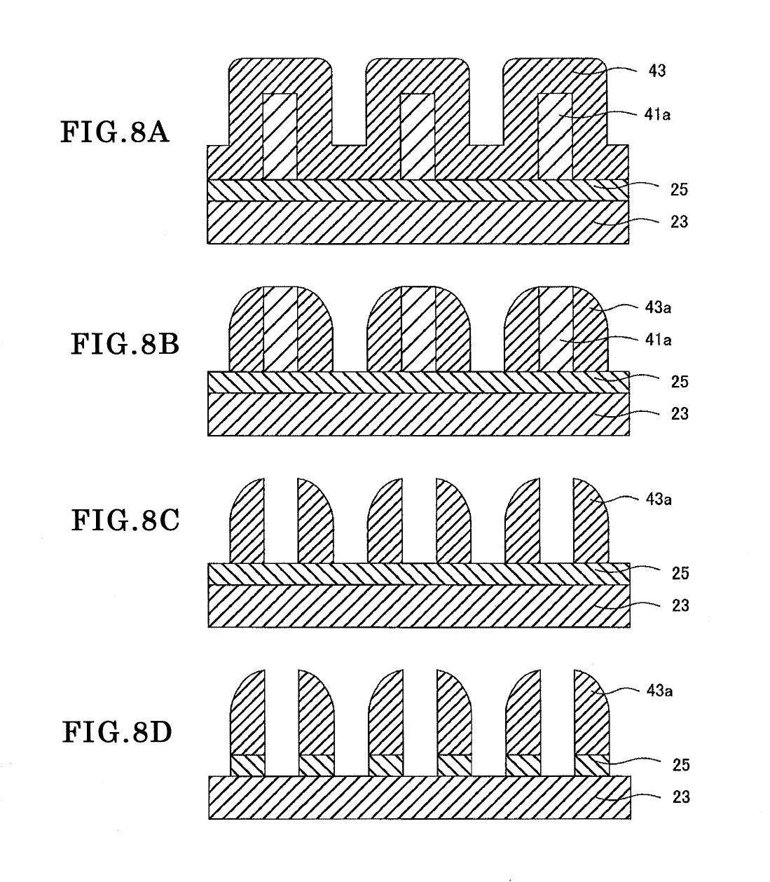

As shown in FIG. 8A, a boron (B) doped silicon oxide film (BSG, Borosilicate Glass) 43 is formed on a surface and a sidewall of the core member 41a and a surface of the silicon nitride film 25 by LPCVD to cover in conformal fashion. A thickness of the B-doped silicon oxide film 43 is set to be slightly larger than the width of the core member 41a, as the thickness becomes smaller in etching process.

As shown in FIG. 8B, the B-doped silicon oxide film 43 other than a sidewall portion formed on the sidewall of the core member 41a is removed by RIE to leave the sidewall portion of the B-doped silicon oxide film 43, so that a sidewall mask film 43a is formed.

As shown in FIG. 8C, the core member 41a is selectively removed using hydrogen fluoride vapor (VPC (Vapor Phase Cleaning)) in which hydrogen fluoride (HF) is used as a solution to leave the sidewall mask film 43a on the silicon nitride film 25. VPC can selectively remove the undoped silicon film 41 to the boron-doped silicon oxide film 43. Further, VPC can selectively remove a phosphorous-doped silicon oxide film to the undoped silicon oxide film 41. Consequently, the B-doped silicon oxide film 43 can be replaced with the P-doped silicon oxide film (PSG). As similarly, the B-doped silicon oxide film 43 can be replaced with a boron and P-doped silicon oxide film (BPSG).

As shown in FIG. 8D, the silicon nitride film 25 is etched dry etching using the sidewall mask film 43a as a mask by. Next, the silicon oxide film 23 is etched using the silicon nitride film 25 as a mask. As a result, the silicon oxide film 23 as a pattern is obtained as the same as the first embodiment as shown in FIG. 4D. Successively, the underlying silicon nitride film 21 and the laminated film as a part of gate electrode 12 in the semiconductor device 1 can be processed using the patterned silicon oxide film 23 as a mask by well-known methods.

As mentioned above, the core member 41a is formed by the undoped silicon oxide film 41 and the sidewall mask film 43a is formed by the boron-doped silicon oxide film 43. In such a manner, a desirable pattern can be formed in the sidewall mask film 43a using the selective ratio in VPC technique. The pattern of the sidewall mask film 43a is finer than the pattern of the silicon oxide film 41 formed by lithography technology.

The same material, silicon oxide, other than a difference of the impurity doping amount are used as the core member 41a and the sidewall mask film 43a. Accordingly, physical properties of the core member 41a and the sidewall mask film 43a are similar. Even when the core member 41a and the sidewall mask film 43a are formed as a state of contacting each other, stress generated at the boundary is restrained. Therefore, even when the core member 41a between the sidewall mask films 43a is removed, tilting the sidewall mask film 43a due to stress is restrained. As a result, the semiconductor device according to the second embodiment has the same effect as the semiconductor device 1 according to the first embodiment.

Further, the undoped silicon oxide film can be used as the core member in the second embodiment as the same as the modification of the first embodiment, where a surface of the core member is nitrided, so that a silicon oxy-nitride film or a silicon nitride film is formed on the core member.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the embodiment as an example describes a case that the film to be processed is a mask film in order to form a gate electrode in a memory cell. However, the film to be processed can be a mask film in order to form an isolation area or can be used in another miniaturization process. Further, a NAND-type flash memory device is described as a semiconductor device, for example. However, another kind of a memory device, a logic device or an embedded device having both a memory area and a logic area can be used.

What is claimed is:

1. A method of fabricating a semiconductor device, comprising:
selectively forming a first film as a core member on a film to be processed;
forming a second film on a side surface and an upper surface of the core member, and on an upper surface of the film to be processed to cover the film, the second film which is constituted with same material as the first film and is doped with impurities being different in amount from impurities in the first film;
removing the second film on the core member and on the film to be processed to form a sidewall mask constituted with the second film on the side surface of the core member;
selectively removing the core member; and
etching the film to be processed using the sidewall mask film as a mask.

2. The method of claim 1, further comprising:
selectively forming a silicon nitride film on the core member after selectively forming the first film and before forming the second film,
removing the nitride film on the core member after removing the core member and the second film on the film to be processed and before selectively removing the core member, and
removing the nitride film after selectively removing the core member and before etching the film to be processed.

3. The method of claim 2, wherein
a film thickness of the nitride film is 0.5 nm or more.

4. The method of claim 2, wherein plasma CVD is used in forming the nitride film.

5. The method of claim 1, wherein
the first film is an undoped polycrystalline silicon film or a phosphorous-doped polycrystalline silicon film, and the second film is a boron-doped polycrystalline silicon film.

6. The method of claim 1, wherein
the first film is an undoped silicon oxide film, and the second film is a boron-doped silicon oxide film or a phosphorous-doped silicon oxide film.

7. The method of claim 1, wherein
a solution selectively etching the first film to the second film is used in selectively removing the core member.

8. The method of claim 7, wherein
the core member is an undoped polycrystalline silicon film or a phosphorous-doped polycrystalline silicon film, and the solution includes coline.

9. The method of claim 7, wherein
the core member is an undoped silicon oxide film and the solution is HF which is used as vapor.

10. The method of claim 1, wherein
the impurities are simultaneously doped in a process where at least one of the first film and the second film is deposited by CVD.
